(19) United States
(12) Patent Application Publication
(10) Pub. No.: US 2024/0262683 A1
(43) Pub. Date: Aug. 8, 2024

(54) HIGH-PRECISION ALIGNMENT METHOD FOR PRODUCING A DEVICE, AND DEVICE

(71) Applicant: ams-OSRAM International GmbH, Regensburg (DE)

(72) Inventors: Nicole Berner, Walderbach (DE); Daniel Richter, Bad Abbach (DE); Gunnar Petersen, Regensburg (DE)

(21) Appl. No.: 18/562,827

(22) PCT Filed: May 18, 2022
(86) PCT No.: PCT/EP2022/063460

§ 371 Date: Nov. 20, 2023

(30) Foreign Application Priority Data
May 21, 2021 (DE) 10 2021 113 303.3

(51) Int. Cl. B81C 3/00; G02B 6/42

(52) U.S. Cl. CPC B81C 3/004; G02B 6/423; B81C 2203/054

(57) ABSTRACT

In an embodiment a method includes providing a coupling element with at least one predefined coupling point, arranging at least one component with a temporary alignment with the predefined coupling point, wherein the component comprises a decoupling point which is approximately aligned with the predefined coupling point of the coupling element, performing an assisted self-alignment of the component with the predefined coupling point, wherein the self-alignment is assisted by utilizing an action of a capillary force on an alignment material which is embedded in the component or attached to the component or by diverting the alignment material, and wherein the decoupling point of the component is moved to the predefined coupling point of the coupling element and adjusted, and permanent fixing of the component to the coupling element after carrying out the assisted self-alignment of the component.

### CROSS-REFERENCE TO RELATED APPLICATIONS

This patent application is a national phase filing under section 371 of PCT/EP2022/063460, filed May 18, 2022, which claims the priority of German patent application 102021113303.3, filed May 21, 2021, each of which is incorporated herein by reference in its entirety.

### TECHNICAL FIELD

A device which is aligned with high-precision is specified. A method for producing a device is also specified, in particular a high-precision alignment method for producing a device which is aligned with high-precision.

### BACKGROUND

A high-precision adjustment of a radiation-emitting component, for example a laser, to a coupling element can take place in the passive state, i.e. without operating the component, or in the active state, i.e. during the operation of the component. If the component is adjusted to the coupling element in the active state, the radiation emitted by the component can be used in the adjustment. In this process, an interconnect material which permits rapid curing is often used. In particular, a UV adhesive is used. This UV adhesive, however, is associated with various drawbacks, for example poor thermal and electrical connection or contamination of the device by organic materials.

When adjusting a component in the switched-off state, the component can be aligned, but with a high level of technical effort via cameras and detection units. However, such a process only permits a series sequence for the alignment of the components. Generally, therefore, the alignment is carried out individually for each component. This results in various drawbacks such as long process times and repeated heating, for example for fixing, in particular for soldering, the components to the coupling element. As a result, the already fastened components are potentially repeatedly subjected to the stress which is produced during the fastening process of the further components.

### SUMMARY

Embodiments provide a reliable, simplified and cost-efficient method for producing a device, in particular for the high-precision alignment of a component or a plurality of components of the device. Further embodiments provide a device which is aligned with high-precision.

According to at least one embodiment of a method, a coupling element is provided with at least one predefined coupling point or with a plurality of predefined coupling points. The coupling element can be formed from a plastics, for example from a polymer or glass. For example, a coupling element made of polymer is used for coupling infrared laser radiation. A coupling element made of glass can be used for coupling visible radiation, in particular visible laser radiation. In particular, the coupling element is formed from a material which is impermeable to radiation or a material which is at most semi-permeable to radiation.

The coupling element can comprise a light guide or a plurality of light guides, for example in the form of (a) light guide cable(s). The light guide can be embedded in the material of the coupling element. In particular, the light guide is optically coupled to one of the coupling points. For example, the light guide extends from the coupling point to a radiation emission face of the coupling element. The coupling element can be a PLC element (planar lightwave circuit element). Alternatively or additionally to the light guide or to the light guides, it is possible that the device comprises lenses or other optical elements. The lenses or the other optical elements are located, in particular, at the coupling points and or at a radiation emission face of the device. The coupling element itself can be a lens or an optical element. The coupling element can be formed from glass. Structures which mark the coupling points can be produced when the coupling element is generated, for example by means of glass molding.

According to at least one embodiment of the method, at least one component is arranged with a temporary approximate alignment with the predefined coupling point of the coupling element. The component comprises a decoupling point which is aligned approximately with the predefined coupling point of the coupling element. This is the case when the decoupling point and the predefined coupling point, in particular, are arranged spatially offset to one another, for example laterally and/or vertically offset. The component is, for example, not yet permanently mechanically connected fixedly to the coupling element. In particular, the component is permanently fastened fixedly to the coupling element only after a precise alignment of the decoupling point of the component with the coupling point of the coupling element.

If the decoupling point is precisely aligned with the coupling point, a radiation emitted from the component can be coupled directly into the coupling element, for example directly into a light guide of the coupling element. In particular, the decoupling point of the component directly adjoins the coupling point of the coupling element.

The decoupling point of the component, in particular, is a radiation emission face of the component. The component can be a radiation-emitting semi-conductor chip, for example a light-emitting diode, or a laser chip. It is possible that a plurality of such components are arranged in each case with an approximate alignment with the respective predefined coupling points.

According to at least one embodiment of the method, the component, in particular the decoupling point of the component, is guided by assisted self-alignment to the predefined coupling point of the coupling element. It is possible that a plurality of components are simultaneously guided in a common method step by the assisted self-alignment with the predefined coupling points of the coupling element.

The process of self-alignment describes, for example, a process by which an appliance, in this case the component, automatically reaches a correct alignment or position. With a self-alignment, the correct alignment or position of the component can be implemented automatically, in particular the correct alignment of the decoupling point of the component with the coupling point of the coupling element. With an assisted self-alignment, the process of self-alignment of the component can be started, maintained or accelerated by the additional action of force. For example, the self-alignment is assisted by utilizing the action of force on an alignment material, whereby the component, in particular the decoupling point of the component, is moved to the predefined coupling point of the coupling element. As a result, the decoupling point of the component can be exactly adjusted to the predefined coupling point of the coupling element. The alignment material can be embedded in the component or indirectly or directly attached or fastened to the component.

According to at least one embodiment of the method, after carrying out the assisted self-alignment, the component or a plurality of components are fastened permanently to the coupling element. The relative position of the decoupling point of the component to the associated coupling point of the coupling element is fixed thereby. The permanent fastening of the component to the coupling element takes place, for example, by heating and/or by cooling an interconnect material. In particular, the interconnect material can be in a liquid aggregate state in the intervening period.

The interconnect material can be electrically conductive. For example, the interconnect material is different from the alignment material. In this case, the alignment material serves only for adjusting the component and does not form a fixed permanent connection between the component and the decoupling element. For example, the interconnect material is a solder material. However, it is also possible that the interconnect material and the alignment material are partially formed from the same material. It is also possible that the alignment material serves not only for aligning the component but at the same time for permanently fixing the component to the coupling element. In the latter case, the interconnect material and the alignment material can be formed from the same material. It is also possible that additional interconnect material, for example in the form of UV adhesive or thermal adhesive, is used for permanently fixing the component to the coupling element.

In at least one embodiment of a method, a coupling element is provided with at least one predefined coupling point. At least one component is arranged with temporary alignment with the predefined coupling point, wherein the component comprises a decoupling point which is aligned approximately with the predefined coupling point of the coupling element. An assisted self-alignment of the component with the predefined coupling point is carried out, wherein the self-alignment is assisted by utilizing an action of force on an alignment material which is embedded in the component or attached to the component. By the assisted self-alignment, the decoupling point of the component is moved to the predefined coupling point of the coupling element and adjusted. In particular, the component is permanently fixed to the coupling element after the assisted self-alignment has been carried out.

The decoupling point of the component is guided automatically and in a simplified and precise manner to the designated coupling point of the coupling element by carrying out the assisted self-alignment of the component by means of the alignment material. The decoupling point is adjusted or precisely aligned with the coupling point when the decoupling point, for example, adjoins the coupling point, in particular directly adjoins the coupling point. The process of assisted self-alignment can be carried out simultaneously for a plurality of components. In particular, a plurality of components can be arranged with temporary alignment with the predefined coupling points of the coupling element before the alignment of the components is simultaneously carried out. The process times and thus also the product costs are reduced thereby.

The components can also be aligned with a high degree of precision in the switched-off state and without additional technical alignment means, such as cameras and detection units. After carrying out the assisted self-alignment, i.e. after adjusting the components to the designated coupling points, a plurality of components, for example, can be fastened simultaneously to the coupling element by the connecting layers being heated once. In contrast to the case in which the components are fixed successively to the coupling element, components which are fixed simultaneously to the coupling element are subjected, in particular, only once to a high temperature and thus only once to the stress produced by the heating and cooling of the interconnect material.

According to at least one embodiment of the method, the alignment material reacts to magnetic fields, wherein the self-alignment of the component with the predefined coupling point is assisted by utilizing the action of magnetic force. The alignment material can be fastened directly to the component. For example, the alignment material can be an external or internal layer of the component. It is possible that the alignment material is embedded entirely inside the component.

The alignment of the component takes place, in particular, by magnetic attraction or repulsion. The component can be guided, for example pulled, by a permanent or electrically generated magnetic field into the corresponding coupling point, for example into a corresponding structuring of the coupling element. At least a partial region of the component can comprise magnetic properties. For example, the component comprises ferromagnetic materials, permanent or electrical nano-magnets or micro magnets. When carrying out the assisted self-alignment of the component, the alignment material or the interconnect material can be present in liquid form or, for example, deformed or liquefied by heating.

According to at least one embodiment of the method, the alignment material is a metallic material. In particular, the alignment material is different from a permanent magnetic material. The action of magnetic force is utilized when assisting the self-alignment of the component, whereby the component is moved to the predefined coupling point due to the action of magnetic force on the metallic alignment material. For example, an external electromagnetic field can be applied, whereby the component is moved, in particular due to magnetic attraction, to the predefined coupling point.

According to at least one embodiment of the method, the alignment material is a permanent magnetic material. The action of magnetic force is utilized when assisting the self-alignment of the component, whereby the component is moved to the predefined coupling point due to the action of magnetic force on the permanent magnetic alignment material. For example, an external electromagnetic field can be applied. In the case of the permanent magnetic material it is also possible that a ferromagnetic metal, which is different from a permanent magnetic material, is used instead of an external electromagnetic field. Such a metal which contains iron, cobalt or nickel, for example, attracts the permanent magnetic alignment material and can guide the component to the predefined coupling point.

According to at least one embodiment of the method, the alignment material is an electromagnet. The action of magnetic force is utilized when assisting the self-alignment of the component, whereby the component is moved to the predefined coupling point due to the action of magnetic force on the electromagnet. The electromagnet can be an electric coil.

According to at least one embodiment of the method, the self-alignment of the component with the predefined coupling point is assisted by utilizing the action of capillary force and/or by diverting the alignment material. In particular, the alignment material is temporarily in a liquid state. Before the alignment material is partially or entirely diverted, the alignment material, for example, directly adjoins the component. The component is entrained by the diversion of the alignment material and can thus reach the predefined coupling point. The diversion of the alignment material is caused, in particular, by the action of capillary force, optionally with the additional assistance of gravity.

According to at least one embodiment of the method, the coupling element comprises at least one alignment channel. The alignment material is partially or entirely diverted by the alignment channel, whereby due to the diversion of the alignment material the component is moved and the decoupling point of the component is guided to the predefined coupling point of the coupling element.

The assisted self-alignment can be carried out by active or passive diversion of the alignment material which at the same time can serve as the interconnect material. The alignment material is in the liquid aggregate state or is liquefied and can flow in a defined direction and through a diversion structure, in particular in the form of an alignment channel.

The predefined exact position of the component can be predetermined by the structuring of the coupling element, for example in the form of stop structures. The diversion of the alignment material can be carried out passively, in particular exclusively or substantially by capillary action and possibly by the action of gravity, or actively, in particular substantially or additionally by magnetic attraction or by negative pressure or by suction.

For example, the alignment channel extends in the vertical or lateral direction through the coupling element. The alignment channel can thus be designed for the diversion of the alignment material, for example for partial or for full diversion of the alignment material.

A lateral direction is understood to mean a direction which, in particular, runs parallel to a main extension surface of the coupling element. A vertical direction is understood to mean a direction which is oriented, in particular, perpendicularly to the main extension surface of the coupling element. The vertical direction and the lateral direction are at right-angles to one another. For example, the coupling element comprises a radiation emission face or a radiation emission point which are located on a side surface of the coupling element, in particular on a side surface of the coupling element extending in the vertical direction. In particular, the radiation emission face comprises a punctiform radiation emission point.

If the alignment material is entirely diverted, in the context of production tolerances at most small residual amounts or small traces of alignment material can be located in the completed device. In this case, the alignment material is not designed for fastening the component. The alignment material is thus different from an interconnect material which is designed for fastening the component.

If the alignment material is partially diverted, after the completion of the device a part of the alignment material can remain in the alignment channel or in a region between the component and the decoupling element. It is thus possible that only a part of the alignment material is diverted and a remaining part of the alignment material serves for fastening the component to the decoupling element. Moreover, it is possible that the decoupling element comprises an internal reservoir which serves as a collecting pan for the alignment material. In this case, it is possible that the alignment channel terminates at the internal reservoir of the decoupling element or at least leads to the internal reservoir. The decoupling element can comprise a further channel which leads outwardly from the internal reservoir. The further channel is designed, in particular, for pressure compensation, whereby the capillary action and thus the diversion of the alignment material is promoted.

According to at least one embodiment of the method, the coupling element comprises at least one stop structure. The stop structure is designed, in particular, to prevent a further movement of the component after the decoupling point of the component has reached the predefined coupling point of the coupling element.

The stop structure can be an integral constituent part of the coupling element, for example in the form of a structuring. The stop structure can be designed in the form of a vertical recess, a vertical elevation, a lateral projection or a lateral indentation. The stop structure can indirectly or directly adjoin the coupling point(s). It is also possible that the stop structure is formed from a material which is different from the material of the coupling element. In the latter case, the stop structure can be arranged on the coupling element or fastened to the coupling element. For example, the stop structure is a vertical elevation on the coupling element.

According to at least one embodiment of the method, a connecting layer is used for fixing the component to the coupling element. The interconnect material of the connecting layer can be different from the alignment material. In particular, in the intervening period the alignment material or the interconnect material is present in the liquid aggregate state at least during the assisted self-alignment or during the fixing of the component. The interconnect material and the alignment material can comprise different melting temperatures. For example, the alignment material comprises a lower melting temperature than the interconnect material.

According to at least one embodiment of the method, the alignment material serves not only for aligning the component but at the same time for permanently fixing the component to the coupling element. The alignment material is, in particular, at the same time the interconnect material. In this case, the alignment material is only partially diverted into the alignment channel. In particular, after a cooling phase, for example after exposure to UV light, the component is fastened permanently by the alignment material to the coupling element.

According to at least one embodiment of the method, the coupling element comprises a plurality of coupling points. A plurality of components can be fastened to a coupling element, wherein the components in each case comprise a decoupling point which is aligned with one of the coupling points of the coupling element. In particular, the components, in particular all of the components, can be simultaneously guided to the coupling points of the coupling element and aligned therewith in a common method step before the permanent fastening. The components, in particular all of the components, can be fastened permanently in a common method process to the coupling element. The common method process for fastening the components to the coupling element can be the process for diverting and cooling the alignment material or the process for melting and cooling the interconnect material which is different from the alignment material. For example, the interconnect material is different from a UV adhesive. The device, in particular, is free of a UV adhesive which is arranged between the component and the coupling element.

The method described herein is particularly suitable for producing a device which is described hereinafter. The features described in connection with the device can thus also be used for the method and vice versa.

In at least one embodiment of a device, it comprises a coupling element and at least one component permanently fixed to the coupling element. The coupling element comprises at least one coupling point. The component comprises a decoupling point which adjoins the coupling point of the coupling element and is aligned therewith. The component comprises a magnetic alignment material or the coupling element comprises at least one alignment channel.

The component can be adjusted with a high degree of precision to the coupling point of the coupling element in a simple manner by an alignment material, in particular a magnetic alignment material, and/or an alignment channel. In particular, the decoupling point of the component directly adjoins the coupling point of the coupling element, whereby the radiation emitted from the component is coupled effectively and without significant losses directly into the coupling point of the coupling element. The component, in particular, is a laser, for example an edge-emitting laser. It is possible that the device comprises a plurality of components, wherein the decoupling points of the components are aligned with the corresponding coupling points of the coupling element.

According to at least one embodiment of the device, the magnetic alignment material is a ferromagnetic metal. The magnetic alignment material can be a permanent magnetic alignment material. It is also possible that the magnetic alignment material is an electromagnetic material. For example, the electromagnetic material forms a coil or a coil structure.

According to at least one embodiment of the device, the alignment channel extends in the vertical or lateral direction through the coupling element. In the vertical and/or lateral direction the alignment channel can comprise a uniform cross section. In particular, the entire alignment channel forms a capillary. Deviating therefrom, it is possible that the alignment channel terminates in the coupling element or the coupling element comprises an internal reservoir. The internal reservoir can comprise a larger cross section in comparison with the alignment channel, for example a cross section which is at least two times, three times, five times or at least ten times greater. The alignment channel can terminate at the internal reservoir or extend through the reservoir.

According to at least one embodiment of the device, the coupling element comprises at least one stop structure. The stop structure is designed, in particular, to align the decoupling point of the component with the coupling point of the coupling element. For example, the stop structure directly adjoins the coupling point and/or the component. The stop structure can be an integral constituent part of the coupling element. For example, the stop structure is designed in the form of a vertical recess, a vertical elevation, a lateral projection or a lateral indentation.

According to at least one embodiment of the device, a light guide is embedded in the coupling element. The light guide can extend in the lateral direction from the coupling point to a radiation emission face or to a radiation emission point of the coupling element. For example, the light guide is a fiber optic cable. The coupling element can comprise a plurality of light guides. The light guides can terminate in each case at one of the coupling points. The light guides can be combined at the radiation emission face of the coupling element.

According to at least one embodiment of the device, it comprises a plurality of components. The coupling element comprises a plurality of coupling points and a plurality of light guides. In particular, the light guides are embedded in the coupling element and in each case are coupled to one of the coupling points. The components can comprise in each case a decoupling point which is aligned with one of the coupling points of the coupling element.

### BRIEF DESCRIPTION OF THE DRAWINGS

Further embodiments and developments of the device or the method for producing the device are found in the following exemplary embodiments which are explained in connection with FIGS. 1A to 10B. In the figures:

FIGS. 1A, 1B and 1C show schematic views of various method steps of an exemplary embodiment of a method for producing a device which, in particular, is shown schematically in FIG. 1B in a sectional view and in FIG. 1C in a plan view;

FIGS. 2A, 2B, 3A, 3B, 4A, 4B, 4C, 4D, 5, 6A, 6B, 6C, 7A, 7B and 7C show schematic views of different method steps for producing different devices and schematic views of different devices according to further exemplary embodiments in sectional views; and

FIGS. 8A, 8B, 9A, 9B, 10A and 10B show schematic views of further method steps for producing further devices and schematic views of further devices according to further exemplary embodiments in sectional views and in plan views.

### DETAILED DESCRIPTION OF ILLUSTRATIVE EMBODIMENTS

Elements which are identical, similar or of identical function are provided with the same reference signs in the figures. The figures in each case are schematic views and thus are not necessarily true to scale. Rather, relatively small elements and, in particular, layer thicknesses are shown excessively large for clarity.

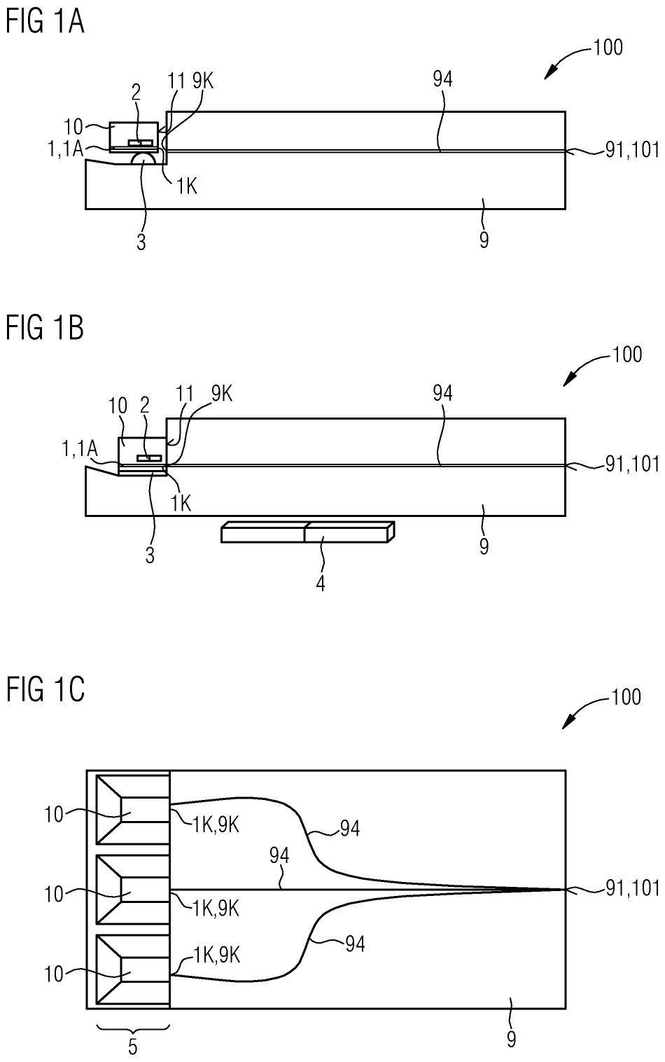

FIG. 1A shows a device 100 with a component 10 and a coupling element 9, wherein the component 10 is arranged on the coupling element 9 before the permanent fastening to the coupling element 9. The component 10 comprises a side surface 11 with a decoupling point 1K. The decoupling point 1K is initially aligned approximately with a coupling point 9K of the coupling element. As shown schematically in FIG. 1A, the decoupling point 1K initially is spatially spaced apart from the coupling point 9K, for example laterally or vertically offset to the coupling point 9K.

The coupling element 9 comprises a side surface 91 which, in particular, is designed as a radiation emission face 91 of the coupling element 9. For example, the side surface 91 of the coupling element 9 forms a side surface 101 or a radiation emission face 101 of the device 100. The coupling element 9 comprises a light guide 94 which extends in the lateral direction from the coupling point 9K to the side surface 91 or 101. It is possible that the radiation emission face 101 comprises a punctiform radiation emission point at which the light guide 94 terminates. It is also possible that the coupling element 9 is formed from a material which is semi-permeable to radiation or a material which is impermeable to radiation. The light guide 94 is embedded in such a material, for example. Such a material, in particular, is different from a glass-like material or from a glass material.

If electromagnetic radiation is coupled into the coupling element 9 at the coupling point 1K, this is forwarded, in particular, exclusively inside the light guide 94, for example due to total reflections inside the light guide 94. The coupled-in radiation, in particular, exits at one end of the light guide 94 on the side surface 91 or 101 from the coupling element 9.

As shown schematically in FIG. 1A, the component 10 is located on a step or in an opening of the coupling element 9 before the permanent fastening to the coupling element 9. In particular, the component 10 comprises a main body 1 with an active zone 1A. For example, the main body 1 is a semi-conductor body. During operation of the component 10, the active zone 1A is designed to generate electromagnetic radiation, for example in the infrared, visible or in the ultraviolet spectral range. The component 10 can be an LED or a laser. For example, the component 10 is designed for generating coherent electromagnetic radiation.

According to FIG. 1A a connecting layer 3 is arranged in the vertical direction between the component 10 and the coupling element 9. Before the permanent fastening of the component 10 to the coupling element 9, the material of the connecting layer 3 can be in a liquid, for example in a viscous, aggregate state in the intervening period. In this state, the position of the component 10 on the connecting layer 3 can be changed. For example, a liquid interconnect material can be applied to the coupling element 9 before the component 10 is arranged on the liquid interconnect material. As a further alternative, it is possible that the material of the connecting layer 3, which is designed as part of the component 10 or as part of the coupling element 9, is present in the solid aggregate state. For aligning the component 10 with the coupling element 9 and for achieving a permanent connection between the component 10 and the coupling element 9, the material of the connecting layer 3 can be deformed or fused, for example, by heating, for example by supplying heat or by applying IR laser radiation.

While the material of the connecting layer 3 is in the liquid, for example in the viscous, aggregate state, the decoupling point 1K of the component 10 can be adjusted or aligned precisely with the coupling point 9K of the coupling element 9. The adjustment or alignment takes place, in particular, by assisted self-alignment.

The component 10 comprises an alignment material 2. According to FIG. 1A the alignment material 2 is embedded in the component 10, in particular in the main body 1 of the component 10. Deviating therefrom, it is possible that the alignment material 2 is attached to the component 10, for example to the main body 1, or to or in a carrier of the component 10. In particular, the alignment material 2 reacts to magnetic fields, wherein the self-alignment of the component 10 with the predefined coupling point 9K is assisted by utilizing the action of magnetic force. If the alignment material 2 reacts to magnetic fields, this can be denoted as a magnetic material. The alignment material 2 in this case can be a ferromagnetic, permanent magnetic or an electromagnetic material.

For example, the ferromagnetic material is different from a permanent magnetic material and/or different from an electromagnetic material and can be a metal such as iron, cobalt or nickel. If the alignment material 2 is an electromagnetic material, this can form an electric coil or a coil structure. For example, the electromagnetic alignment material 2 is an electric coil made from an electrically conductive metal, for example from copper. By electrical activation of the coil or the coil structure, the component 10 can interact with an external magnetic material, in particular with an external magnetic field, and be guided, for example pulled, to the predefined position.

The magnetic action on the alignment material 2 is shown schematically in FIG. 1B. Due to the magnetic or electromagnetic interactions between the alignment material 2 and an external magnetic material 4, the decoupling point 1K of the component 10 is self-aligned with the coupling point 9K of the coupling element 9. The self-alignment of the component 10 or the decoupling point 1K of the component 10 with the predefined coupling point 9K of the coupling element 9 is thus assisted by the action of magnetic force. The external magnetic material 4 can be a ferromagnetic material, a permanent magnetic material or an electromagnetic material. In particular, the component 10 is moved toward the predefined coupling point 9K due to the action of magnetic force on the alignment material.

While in FIG. 1B it is schematically shown that both the alignment material 2 and the external magnetic material 4 are permanent magnets, i.e. form a {permanent magnet; permanent magnet} pair, other combinations or pairs are possible, for example (magnetic metal; permanent magnet}, {magnetic metal; electromagnet} or {permanent magnet; electromagnet}.

After the decoupling point 1K is aligned with the coupling point 9K, the component 10 can be permanently fixed to the coupling element 9. This takes place, for example, by curing the connecting layer 3. Since the decoupling point 1K is aligned with the coupling point 9K, the radiation emitted by the component 10 can be coupled directly, in particular without losses, into the coupling point 9K of the coupling element 9. In particular, the decoupling point 1K directly adjoins the coupling point 1K.

The device 100, shown in FIG. 1C in plan view, corresponds substantially to the device 100 shown in FIG. 1B. In contrast thereto, the device 100 comprises a plurality of components 10. In particular, the device 10 comprises three components 10. Each of the components 10 comprises a decoupling point 1K which is aligned with one of the coupling points 9K of the coupling element 9.

The coupling element 9 comprises a plurality of coupling points 9K and a plurality of light guides 94. The light guides 94 extend in each case in the lateral direction from one of the coupling points 9K to a side surface 91 of the decoupling element 9 opposing the decoupling point 9K. In particular, the side surface 91 forms a side surface 101 of the device 100 which is designed, for example, as a radiation emission face of the device 100. The light guides 94 are combined on the side surface 91. It is possible that the components 10 emit radiation of different wavelengths. For example, the components 10 emit red, green and blue light. By combining the light guides 94, the device 100 can emit white light as a whole by mixing the radiations.

Deviating from FIG. 1C, it is possible that the device 100 comprises a different number of components 10. Moreover, it is possible that the coupling element 9 does not comprise exactly three light guides 94 but a different number of light guides 94. Moreover, it is possible that the light guides 94 are not combined at the side surface 91.

As shown schematically in FIG. 1C, the coupling element 9 comprises a plurality of recesses 5 in which the components 10 are arranged. The recesses 5 are laterally spaced apart from one another. It is possible that exactly one component 10 is arranged in exactly one recess 5. The recess 5 comprises, in particular, oblique side walls. The component 10 can be arranged on an oblique side wall of the recess 5 before carrying out the assisted self-alignment. During the assisted self-alignment, the component 10 can be moved along the oblique side wall of the recess 5 to the predefined coupling point 9K. In particular, the recess 5 comprises a bottom surface, the geometry thereof being adapted to the geometry of the component 10. In this sense, the recess 5 can serve as a stop structure which prevents a further movement of the component 10 after the decoupling point 1K of the component 10 has reached the predefined coupling point 9K of the coupling element 9.

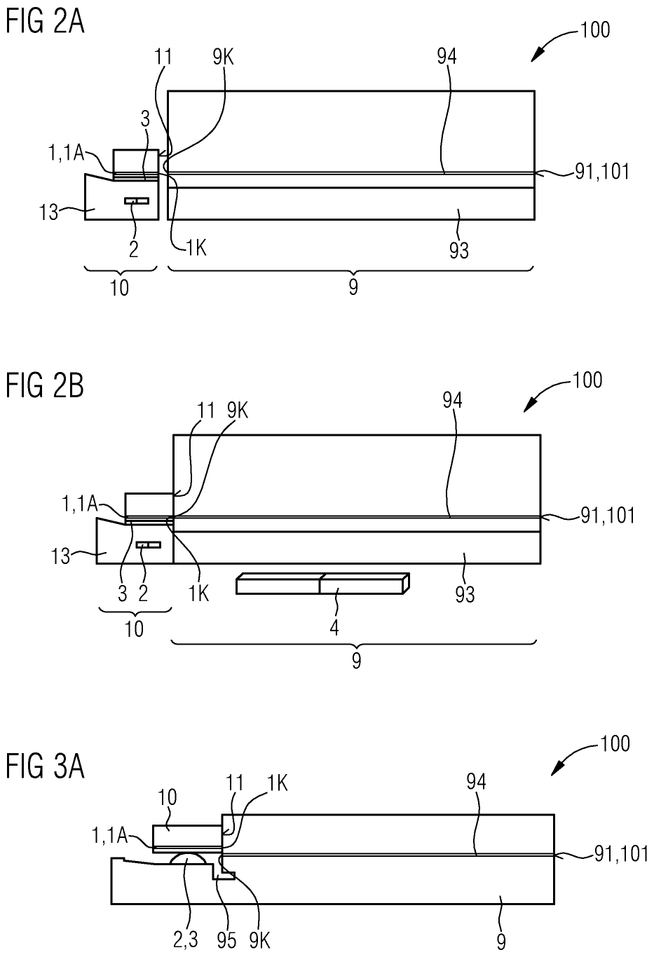

The exemplary embodiment shown in FIGS. 2A and 2B of a device 100 or a method for producing a device 100 corresponds substantially to the exemplary embodiment shown in FIGS. 1A and 1B of a device 100 or a method for producing a device 100. In contrast thereto, it is explicitly shown that the alignment material 2 is embedded in a carrier 13 of the component 10 or is attached to the carrier 13. The coupling element 9 can comprise a main body with the light guide 94 and a carrier 93, wherein the main body is arranged on the carrier 93 of the coupling element 9. Before the permanent fixing of the component 10 to the coupling element 9, the component 10 can be initially arranged laterally spaced apart from the coupling element 9. During the assisted self-alignment, the component 10 is moved toward the coupling element 9 and adjusted.

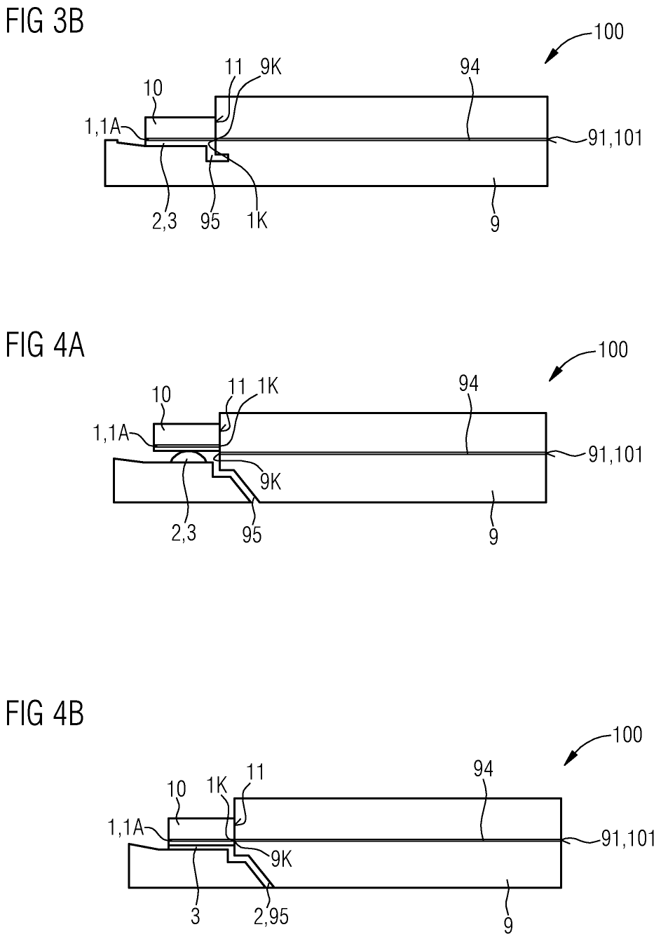

The exemplary embodiment shown in FIGS. 3A and 3B of a device 100 or a method for producing a device 100 corresponds substantially to the exemplary embodiment shown in FIGS. 1A and 1B of a device 100 or a method for producing a device 100. In contrast thereto, the alignment material 2 serves not only for aligning the component 10 but at the same time for permanently fixing the component 10 to the coupling element 9. In this sense, the connecting layer 3 can be formed from the alignment material 2.

The decoupling element 9 comprises at least one alignment channel 95. The alignment channel 95 is designed, in particular, for diverting the alignment material 2. The component 10 can be moved by the diversion of the alignment material 2, whereby the decoupling point 1K of the component 10 is guided to the predefined coupling point 9K of the coupling element 9.

For example, the alignment channel 95 is an alignment capillary. The self-alignment of the component 10 to the predefined coupling point 9K is assisted, in particular, by utilizing the action of capillary force and/or by diverting the alignment material 2. The alignment channel 95 can be filled partially or entirely by the alignment material 2 after the diversion of the alignment material 2.

Deviating from FIG. 3A, it is possible that the alignment material 2 is different from an interconnect material of the connecting layer 3. For example, the alignment material 2 is arranged at least in some regions between the coupling element 9 and the connecting layer 3. After the diversion of the alignment material 2 into the alignment channel 95, the remaining connecting layer 3 can be used for permanently fixing the component 10 to the coupling element 9.

Deviating from FIGS. 3A and 3B, it is possible that the coupling element 9 comprises an additional internal reservoir which serves as a collecting pan for the alignment material 2. In this case, it is possible that the alignment channel 95 terminates at the internal reservoir or at least leads to the internal reservoir.

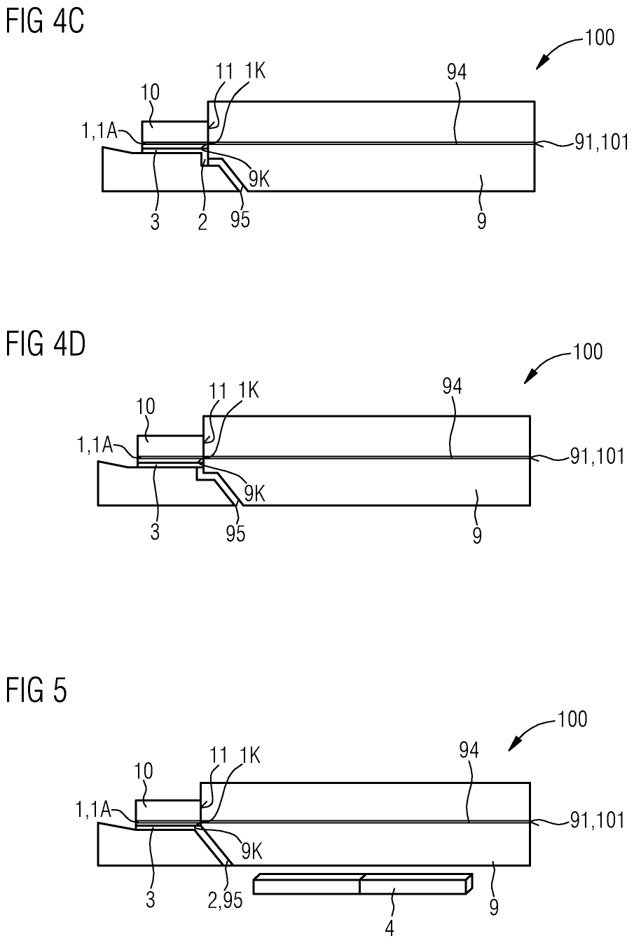

The exemplary embodiment shown in FIGS. 4A and 4B of a device 100 or a method for producing a device 100 corresponds substantially to the exemplary embodiment shown in FIGS. 3A and 3B of a device 100 or a method for producing a device 100. In contrast thereto, it is explicitly shown that the alignment channel 95 extends in the vertical direction through the coupling element 9. In this case, the capillary action is additionally reinforced by the action of gravity. As shown schematically in FIG. 4B, the alignment channel 95 can be filled up entirely with the alignment material 2 after the completion of the device 100.

The exemplary embodiment shown in FIG. 4C of a device 100 corresponds substantially to the device 100 shown in FIG. 4B. In contrast thereto, the alignment channel 95 is only partially filled with the alignment material 2 after the completion of the device 100. Regions of the alignment channel 95 which are not filled with the alignment material 2 can be filled with a gaseous medium, for example with air.

The exemplary embodiment shown in FIG. 4D of a device 100 corresponds substantially to the device 100 shown in FIG. 4B or 4C. In contrast thereto, the alignment channel 95 is free of the alignment material 2 after the completion of the device 100. In particular, the alignment material 2 is entirely diverted out of the coupling element 9. The entire alignment channel 95 can be filled with a gaseous medium, for example with air.

According to FIGS. 4A to 4D, the alignment material 2 can be different from a magnetic material, i.e. different from a material which reacts to magnetic fields. In contrast thereto, it is shown schematically in FIG. 5 that the alignment material 2 can be a magnetic material. The diversion of the alignment material 2 can thus be actively controlled, so that the decoupling point 1K can be guided actively and very precisely to the coupling point 9K. In contrast to FIG. 5, the diversion according to FIGS. 4A to 4D takes place passively, namely merely by utilizing the capillary action and the action of gravity.

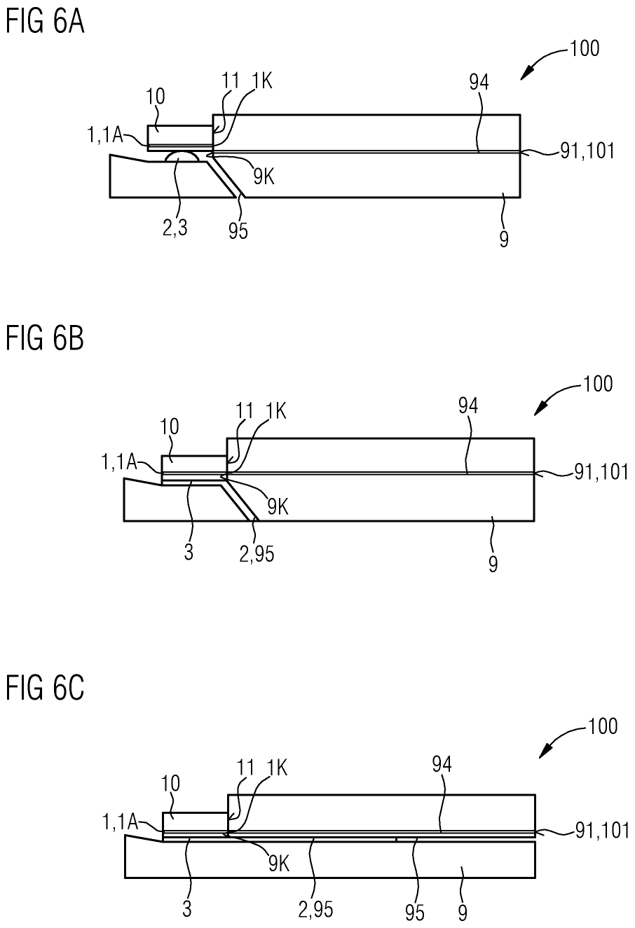

The exemplary embodiments shown in FIGS. 6A, 6B and 6C correspond substantially to the exemplary embodiment shown in FIG. 4A or 4D. In contrast thereto, the alignment channel 95 is designed as a straight alignment channel 95 without branches or deviations. According to FIG. 6C the alignment channel 95 extends in the lateral direction through the coupling element 9. The diversion of the alignment material 2 can be designed passively or actively. Moreover, the alignment material 2 can be different or identical, in comparison with a material of the connecting layer 3. The alignment material 2 can become or be partially or entirely diverted from the coupling element 9.

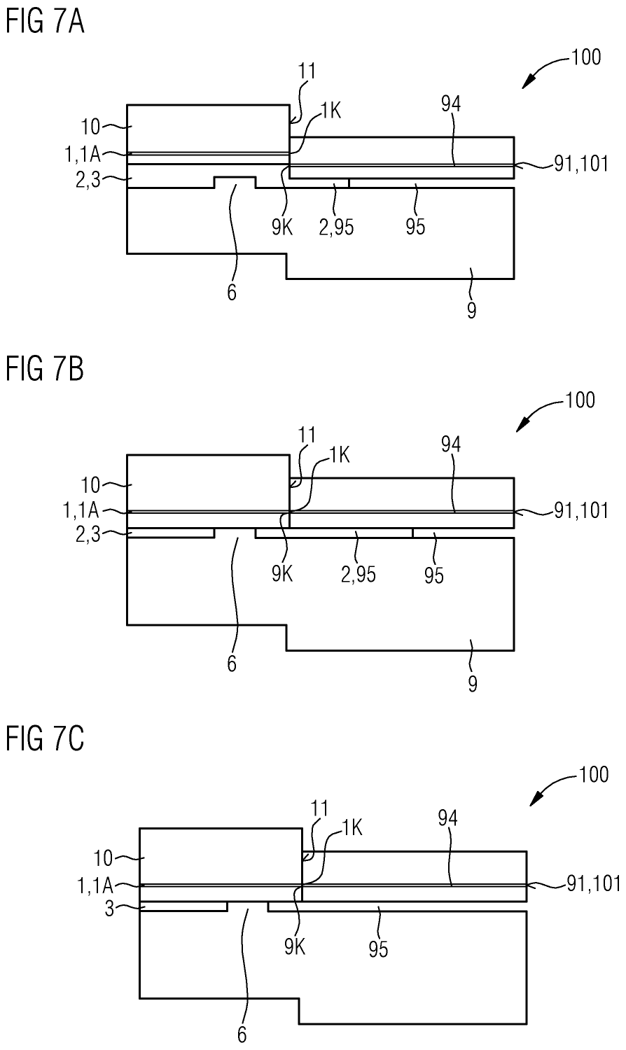

The exemplary embodiment shown in FIG. 7A of a method step for producing a device 100 corresponds substantially to the exemplary embodiment shown in FIG. 6A or 6C. In contrast thereto, the coupling element 9 comprises a stop structure in the form of an alignment edge 6. The alignment edge 6 is, in particular, a vertical elevation or a step of the coupling element 9. The alignment edge 6 is, in particular, an overflow structure. A residual amount of alignment material 2 or interconnect material 3, which is available for the connection of the component 10 to the coupling element, can be ensured by the alignment edge 6, in particular in the form of an overflow structure, for example when cooling the liquefied alignment material or interconnect material or when curing the alignment material 2 or the interconnect material 3, which can be present in the liquid aggregate state during the entire adjustment process.

In plan view, initially the alignment edge 6 is entirely covered by the alignment material 2, wherein the alignment material 2 is arranged in the vertical direction between the component 10 and the alignment edge 6. The component 10 is thus separated by the alignment material 2 from the alignment edge 6. During the diversion of the alignment material 2, in particular into the alignment channel 95, the lateral spacing between the component 10 and the alignment edge 6 reduces until the component 10 comes into contact with the alignment edge 6 and a further movement of the component 10 is stopped thereby. This is shown schematically in FIG. 7B.

In particular, a vertical height of the alignment edge 6 is adapted to the vertical position of the decoupling point 1K and/or the vertical position of the coupling point 9K, such that a further movement of the component 10 is then stopped precisely when the decoupling point 1K is adjusted or aligned with the coupling point 9K. FIGS. 7B and 7C show two different exemplary embodiments of a device 10 after the completion thereof. According to FIG. 7B, the alignment channel 95 can be partially filled with the alignment material 2. According to FIG. 7C, the alignment material 2 can be diverted entirely from the coupling element 9. In this case, the alignment channel 95 is substantially free of the alignment material 2, apart from residual traces.

For the active diversion of the alignment material 2 a negative pressure can be generated or actively pumped. The alignment material 2, in particular, is diverted actively or passively only until the component 10 comes into contact with the alignment edge 6 in the form of an overflow edge. In the absence of the alignment channel 95 and/or a discharge reservoir, the active diversion of the alignment material 2 can alternatively or additionally be carried out by the action of magnetic force.

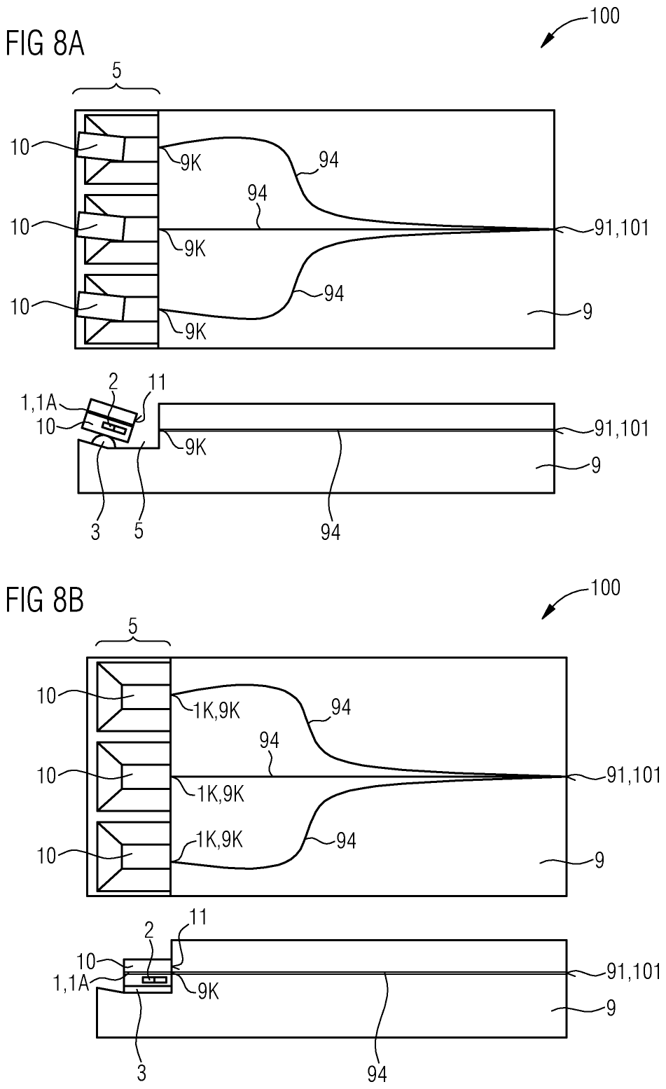

FIGS. 8A and 8B show exemplary embodiments of a device 100 before the alignment of the component 10 or after the alignment of the component 10, in each case in plan view and in sectional view. According to FIG. 8A, the coupling element 9 comprises a plurality of local recesses 5. The recesses 5 form stop structures, which prevents a further movement of the component 10 after the component 10 is aligned or adjusted with the coupling point 9K. The component 10 can be arranged on an oblique side wall of the recess 5 before the assisted self-alignment.

FIG. 8A shows a plurality of components 10 which are arranged in each case on a side wall of the recess 5, before carrying out the assisted self-alignment. During the assisted self-alignment, the components 10 in each case slip toward the bottom surface of a recess 5 and are stopped after the decoupling points 1K are aligned with the coupling points 9K (FIG. 8B). The alignment of the components 10 takes place, in particular, simultaneously in a common method step.

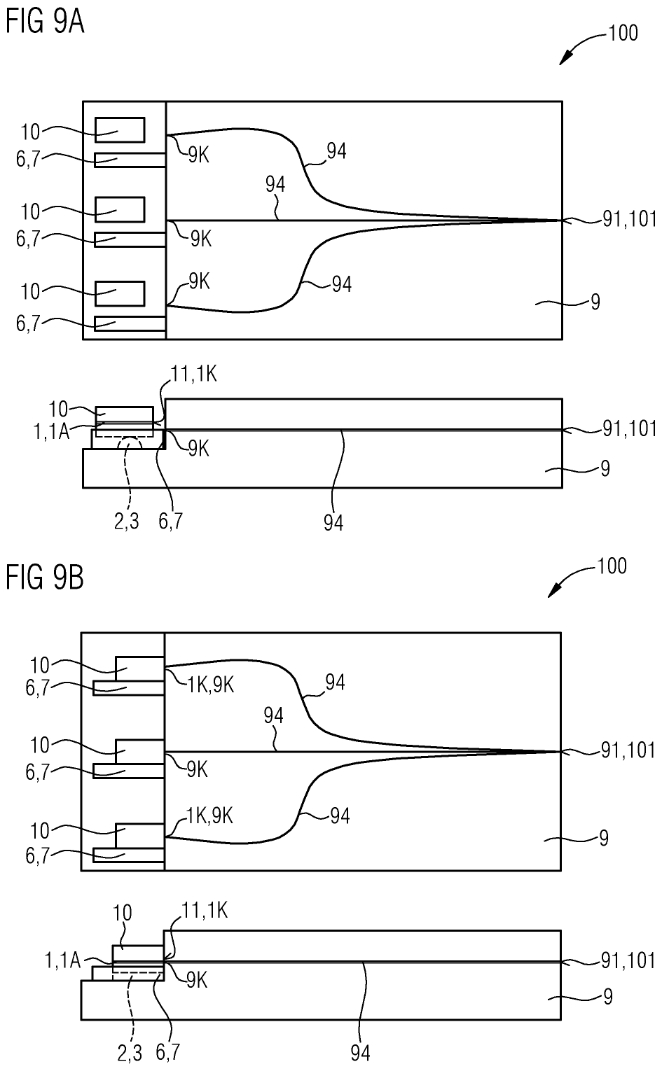

The exemplary embodiment of a method step shown in FIG. 9A corresponds substantially to the exemplary embodiment of a method step shown in FIG. 8A. In contrast thereto, the stop structure is designed, in particular, as a vertical elevation 6 of the coupling element 9 or as a lateral projection 7 of the coupling element 9. FIG. 9A shows the device 100 before carrying out the assisted self-alignment of the components 10 which are initially aligned approximately with the coupling points 9K. FIG. 9B shows the device 100 after carrying out the assisted self-alignment of the components 10, after the components 10 are aligned precisely with the coupling points 9K and fixed permanently to the decoupling element 9.

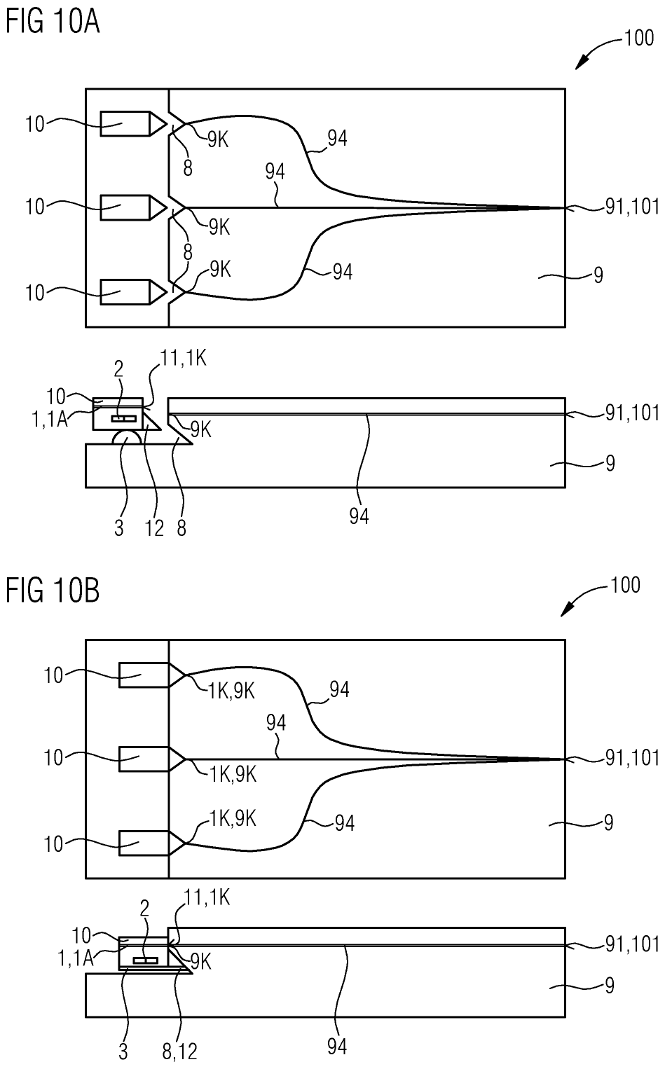

The exemplary embodiment of a method step shown in FIG. 10A corresponds substantially to the exemplary embodiment of a method step shown in FIG. 8A or 9A. In contrast thereto, the stop structure is designed, in particular, as a lateral indentation 8 of the coupling element 9. The component 10 can comprise a projection 12 which is designed in a complementary manner to the lateral indentation 8 of the coupling element 9. For example, the projection 12 is designed in a wedge-shaped manner. FIG. 10A shows the device 100 before carrying out the assisted self-alignment of the components 10 which are initially aligned approximately with the coupling points 9K. FIG. 10B shows the device 100 after carrying out the assisted self-alignment of the components 10, after the components 10 are aligned precisely with the coupling points 9K and permanently fixed to the decoupling element 9. In particular, the projection 12 of the component 10 and the indentation 8 of the coupling element 9 form a tongue and groove structure.

Shorter process times and thus lower product costs can be achieved by the assisted self-alignment. The adjustment process can take place independently of the interconnect material. In comparison with UV adhesive, it is not necessary for the interconnect material to assist with the so-called snap curing, for example. Moreover, repeated curing is not required when, for example, a plurality of components are adjusted and permanently fixed in succession. With the assisted self-alignment, a plurality of components can be simultaneously positioned and permanently fixed to the coupling element by curing a connecting layer at exactly predefined positions.

The invention is not limited by the description of the invention based on the exemplary embodiments. Rather, the invention encompasses any novel feature and any combination of features which, in particular, contains any combination of features in the claims, even if this feature or this combination is not explicitly specified per se in the claims or exemplary embodiments.

1-19. (canceled)

20. A method for producing a device, the method comprising:
providing a coupling element with at least one predefined coupling point;
arranging at least one component with a temporary alignment with the predefined coupling point, wherein the component comprises a decoupling point which is approximately aligned with the predefined coupling point of the coupling element;
performing an assisted self-alignment of the component with the predefined coupling point, wherein the self-alignment is assisted by utilizing an action of a capillary force on an alignment material which is embedded in the component or attached to the component or by diverting the alignment material, and wherein the decoupling point of the component is moved to the predefined coupling point of the coupling element and adjusted; and
permanent fixing of the component to the coupling element after carrying out the assisted self-alignment of the component.

21. The method as claimed in claim 20, wherein the coupling element comprises at least one alignment channel, the alignment material being partially or entirely diverted thereby, and wherein, due to a diversion of the alignment material, the component is moved and the decoupling point of the component is guided to the predefined coupling point of the coupling element.

22. The method as claimed in claim 20, wherein an alignment channel extends in a vertical or lateral direction through the coupling element and the alignment channel is configured for diverting the alignment material.

23. The method as claimed in claim 20, wherein the coupling element comprises at least one stop structure which prevents a further movement of the component after the decoupling point of the component has reached the predefined coupling point of the coupling element.

24. The method as claimed in claim 23, wherein the stop structure is an integral constituent part of the coupling element, and wherein the stop structure comprises a vertical recess, a vertical elevation, a lateral projection or a lateral indentation.

25. The method as claimed in claim 20, wherein a connecting layer is used for fixing the component to the coupling element, and wherein a material of the connecting layer is different from the alignment material and is present in a liquid aggregate state in an intervening period, at least while performing the assisted self-alignment or while permanently fixing the component.

26. The method as claimed in claim 20, wherein the alignment material serves not only for aligning the component but at the same time for permanently fixing the component to the coupling element.

27. The method as claimed in claim 20,
wherein the coupling element comprises a plurality of coupling points,
wherein a plurality of components are fastened to the coupling element, each of the components comprises a decoupling point which is aligned with one of the coupling points of the coupling element, and
wherein the components are simultaneously aligned with the coupling points of the coupling element in a common method step before fixing.

28. A device comprising:
a coupling element and at least one component permanently fixed to the coupling element,
wherein the coupling element comprises at least one coupling point,
wherein the component comprises a decoupling point which adjoins the coupling point of the coupling element and is aligned therewith, and
wherein the coupling element comprises at least one alignment channel.

29. The device as claimed in claim 28, wherein the alignment channel extends in a vertical direction through the coupling element.

30. The device as claimed in claim 28, wherein the alignment channel extends in a lateral direction through the coupling element.

31. The device as claimed in claim 28,
wherein the coupling element comprises at least one stop structure configured to align the decoupling point of the component with the coupling point of the coupling element,
wherein the stop structure is an integral constituent part of the coupling element, and
wherein the stop structure is a vertical recess or a vertical elevation.

32. The device as claimed in claim 28,
wherein the coupling element comprises at least one stop structure configured to align the decoupling point of the component with the coupling point of the coupling element,
wherein the stop structure is an integral constituent part of the coupling element, and
wherein the stop structure is a lateral projection or a lateral indentation.

33. The device as claimed in claim 28, further comprising a light guide embedded in the coupling element, the light guide extending in the lateral direction from the coupling point to a radiation emission face of the coupling element.

34. The device as claimed in claim 28,
wherein the device comprises a plurality of components,
wherein the coupling element comprises a plurality of coupling points and a plurality of light guides,
wherein the light guides are embedded in the coupling element and in each case are coupled to one of the coupling points, and
wherein the components comprise in each case a decoupling point which is aligned with one of the coupling points of the coupling element.
